(19) United States
(12) Patent Application Publication
(10) Pub. No.: US 2013/0278332 A1
(43) Pub. Date: Oct. 24, 2013

(54) DOHERTY AMPLIFYING APPARATUS AND METHOD

(71) Applicant: ELECTRONICS AND TELECOMMUNICATIONS RESEARCH INSTITUTE, (US)

(72) Inventors: Hong Gu JI, Daejeon (KR); In Bok YOM, Daejeon (KR)

(73) Assignee: ELECTRONICS AND TELECOMMUNICATIONS RESEARCH INSTITUTE, Daejeon (KR)

(21) Appl. No.: 13/793,164

(22) Filed: Mar. 11, 2013

(30) Foreign Application Priority Data
Apr. 23, 2012 (KR) 10-2012-0041977

(51) Int. Cl. H03F 1/32

(52) U.S. Cl. CPC H03F 1/3241
USPC 330/124 R

(57) ABSTRACT

Disclosed is a Doherty amplifying apparatus and method that ensures efficiency in linearity of an input signal by linearizing an applied signal using a linearization unit by analog pre-distortion, and amplifying the linearized signal using a primary amplifier and a secondary amplifier.

### CROSS-REFERENCE TO RELATED APPLICATION

This application claims the priority benefit of Korean Patent Application No. 10-2012-0041977, filed on Apr. 23, 2012, in the Korean Intellectual Property Office, the disclosure of which is incorporated herein by reference.

### BACKGROUND

1. Field of the Invention

The present invention relates to a Doherty amplifying apparatus and method that enhances linearity.

2. Description of the Related Art

In general, a communication device may use a modulation signal in a peak to average power ratio (PAPR) scheme for transmitting a large amount of information, and reducing efficiency by causing a rapid power consumption of an amplifying apparatus.

A Doherty amplifying structure among various structures of the amplifying apparatus is widely utilized in a power amplifying apparatus of a base station, a repeater, and a mobile terminal since the Doherty amplifying structure may guarantee improved efficiency in a broad output power range.

FIG. 1 is a diagram illustrating a configuration of a Doherty amplifying apparatus according to a conventional art.

Referring to FIG. 1, the conventional Doherty amplifying apparatus may include a distributor 110 to distribute an input signal that is applied, a primary amplifier 120 and a secondary amplifier 130 to amplify distributed input signals respectively, and an impedance converting unit to compensate for a phase difference of the primary amplifier 120 and the secondary amplifier 130.

In the conventional Doherty amplifying apparatus, an operation point of the primary amplifier 120 may perform an operation of class B or class AB, and an operation point of the secondary amplifier 130 may perform an operation of class C.

Accordingly, the conventional Doherty amplifying apparatus may cause a linearity distortion due to characteristics degradation as characteristics of amplitude modulation to amplitude modulation (AM to AM) or amplitude modulation to phase modulation (AM to PM) may be deteriorated.

When used in the base station or the repeater that requires a strict linearity, the Doherty amplifying apparatus may be unable to be used in a range of a frequency greater than 10 gigahertz (GHz) due to a complex structure and a limited frequency since the Doherty amplifying apparatus may be employed as an envelope tracking, an adaptive power device, a feedforward, a digital pre-distortion, and the like.

### SUMMARY

According to an aspect of the present invention, there is provided a Doherty amplifying apparatus, including a linearization unit to linearize an applied signal through an analog pre-distortion, a primary amplifier to amplify the linearized signal, and a secondary amplifier to amplify the linearized signal.

The primary amplifier and the secondary amplifier may amplify the linearized signal based on differing operation points.

The linearization unit may be combined to a front portion of the primary amplifier.

The linearization unit may be combined to a front portion of the secondary amplifier.

The linearization unit may be combined to a front portion of the primary amplifier and the secondary amplifier.

The linearization unit may detect an inter-modulation distortion (IMD) component of the applied signal.

The linearization unit may perform inverse phasing with respect to a signal from which the IMD component is detected and thereby apply the inverse-phased signal to the primary amplifier or the secondary amplifier.

According to an aspect of the present invention, there is provided a Doherty amplifying method, including linearizing an applied signal using a linearization unit through an analog pre-distortion, amplifying the linearized signal using a primary amplifier, and amplifying the linearized signal using a secondary amplifier.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a diagram illustrating a configuration of a Doherty amplifying apparatus according to a conventional art;

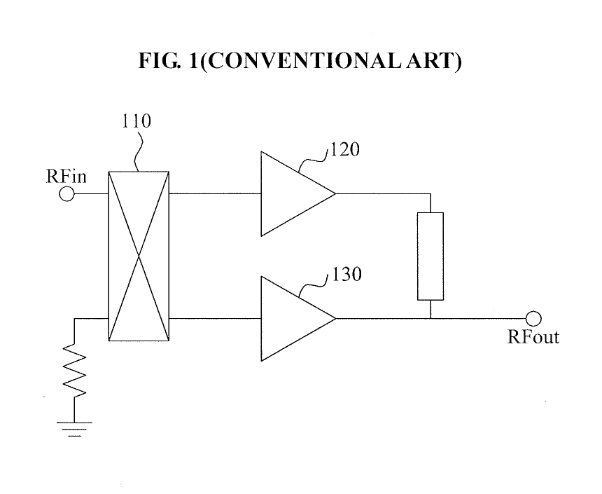

FIG. 2 is a block diagram illustrating a configuration of a Doherty amplifying apparatus according to an embodiment of the present invention;

FIG. 3 is a flowchart illustrating a Doherty amplifying method according to an embodiment of the present invention;

FIG. 4 is a diagram illustrating a configuration of an analog pre-distorter included in a linearization unit according to an embodiment of the present invention; and

FIG. 5 is a flowchart illustrating a pre-distortion method according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

When it is determined that a detailed description related to a related known function or configuration which may make the purpose of the present invention unnecessarily ambiguous in the description of the present invention, such detailed description will be omitted. Also, terminologies used herein are defined to appropriately describe the exemplary embodiments of the present invention and thus may be changed depending on a user, the intent of an operator, or a custom. Accordingly, the terminologies must be defined based on the following overall description of this specification.

A Doherty amplifying apparatus according to an embodiment of the present invention may ensure linearity by inserting an analog pre-distortion linearization unit to a primary amplifier or a secondary amplifier.

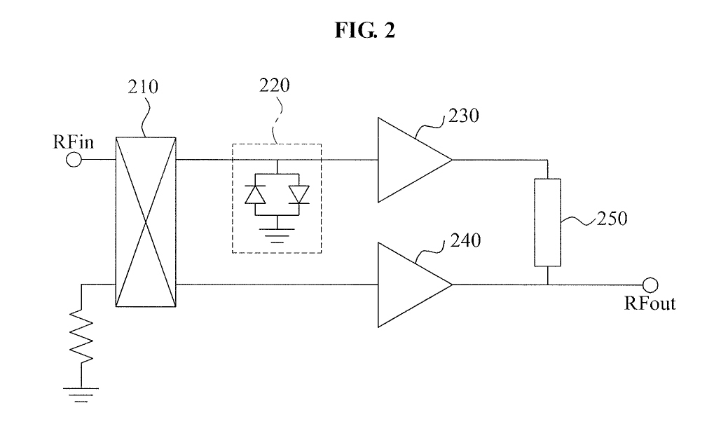

FIG. 2 is a block diagram illustrating a configuration of a Doherty amplifying apparatus according to an embodiment of the present invention.

Referring to FIG. 2, the Doherty amplifying apparatus may include a linearization unit 220 to linearize an applied signal through analog pre-distortion, a primary amplifier 230 to amplify the linearized signal, and a secondary amplifier 240 to amplify the linearized signal.

Also, the Doherty amplifying apparatus may include a distributor 210 to distribute an input signal (RFin) that is applied, and may further include an impedance converting unit 250 to compensate for a phase difference of the primary amplifier 230 and the secondary amplifier 240.

The Doherty amplifying apparatus may be used up to a millimeter wave band having a relatively high frequency when compared to a digital pre-distorter, by inserting the linearization unit 220 including the analog pre-distorter, and may be applied to a high frequency integrated linearizing Doherty amplifying apparatus since manufacturing of a monolithic microwave integrated circuit (MMIC) is possible.

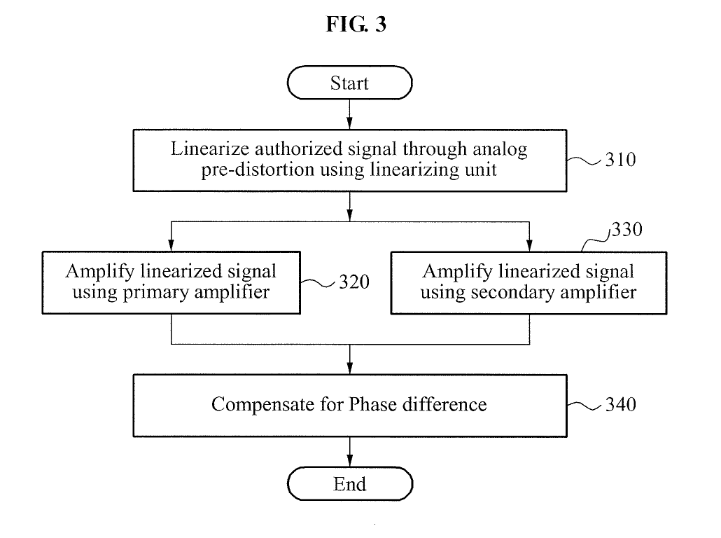

Hereinafter, a method for amplifying an input signal through linearizing using a Doherty amplifying apparatus according to an embodiment of the present invention will be described with reference to FIG. 3.

FIG. 3 is a flowchart illustrating a Doherty amplifying method according to an embodiment of the present invention.

Referring to FIGS. 2 and 3, in operation 310, the Doherty amplifying apparatus may linearize an applied signal through an analog pre-distortion.

The primary amplifier 230 and the secondary amplifier 240 may amplify the linearized signal based on differing operation points.

For example, the Doherty amplifying apparatus may be configured based on different classes such as class A or class AB, and the primary amplifier 230 and the secondary amplifier 240 may be configured to operate in the different classes.

The Doherty amplifying apparatus may compensate for a linearity of an amplifying apparatus by inserting the linearization unit 220 including an analog pre-distorter to a pre-frame of the primary amplifier 230 or the secondary amplifier 240.

When degradation in linearzing occurs, the Doherty amplifying apparatus may readily connect a circuit by inserting the linearization unit 220 to the front portion of the primary amplifier 230 and the secondary amplifier 240, and linearize the circuit up to a high frequency band to improve a linearizing performance.

The Doherty amplifying apparatus may amplify the linearized signal using the primary amplifier 230 in operation 320, and amplify the linearized signal using the secondary amplifier 240 in operation 330.

In operation 340, the Doherty amplifying apparatus may compensate for a phase difference of the primary amplifier 230 and the secondary amplifier 240.

The linearization unit 220 may be combined to a front portion of the primary amplifier 230.

The linearization unit 220 may be combined to a front portion of the secondary amplifier 240.

The linearization unit 220 may be combined to a front portion of the primary amplifier 230 and the secondary amplifier 240.

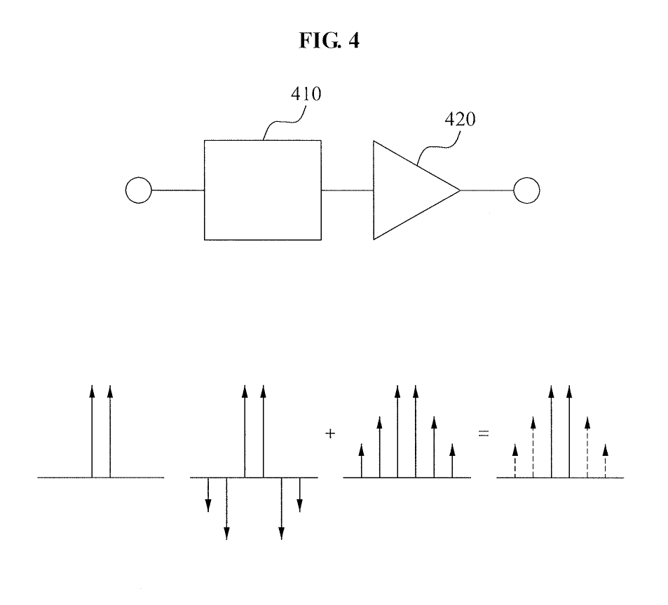

FIG. 4 is a diagram illustrating a configuration of an analog pre-distortion included in a linearization unit according to an embodiment of the present invention.

Referring to FIG. 4, the linearization unit may detect an inter-modulation distortion (IMD) component of the signal applied, through a detecting unit 410.

The linearization unit may perform inverse phasing with respect to the signal from which the IMD component is detected and apply the inverse-phased signal to the primary amplifier or the secondary amplifier.

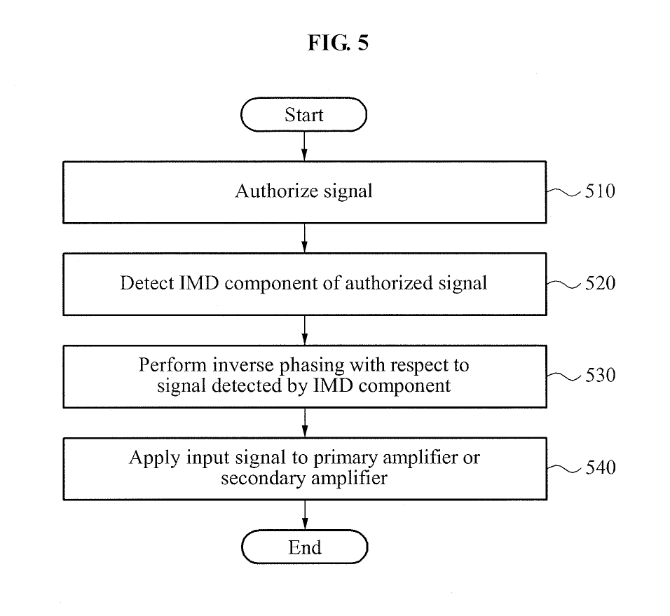

FIG. 5 is a flowchart illustrating a pre-distortion method according to an embodiment of the present invention.

Referring to FIG. 5, the linearization unit may apply an input signal through a distributor, and detect the IMD component of the applied signal in operation 520.

In operation 530, the linearization unit may perform inverse phasing with respect to the signal from which the IMD component is detected and apply the inverse-phased signal to the primary amplifier or the secondary amplifier in operation 540.

For example, when the input signal, that is, a radio frequency (RF) signal, is applied, the linearization unit may achieve linearity by removing the IMD component, that is, an inverse-phase component, by detecting the IMD component from a pre-distorter to make the IMD component inverse-phased and applying the IMD component in an input portion of an amplifier.

According to an embodiment of the present invention, an analog pre-distortion linearization unit may be inserted in a Doherty amplifying apparatus, such that efficiency may be improved and a linearity may be achieved up to a millimeter wave band.

The above-described exemplary embodiments of the present invention may be recorded in computer-readable media including program instructions to implement various operations embodied by a computer. The media may also include, alone or in combination with the program instructions, data files, data structures, and the like. Examples of computer-readable media include magnetic media such as hard disks, floppy disks, and to magnetic tape; optical media such as CD ROM discs and DVDs; magneto-optical media such as floptical discs; and hardware devices that are specially configured to store and perform program instructions, such as read-only memory (ROM), random access memory (RAM), flash memory, and the like. Examples of program instructions include both machine code, such as produced by a compiler, and files containing higher level code that may be executed by the computer using an interpreter. The described hardware devices may be configured to act as one or more software modules in order to perform the operations of the above-described exemplary embodiments of the present invention, or vice versa.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A Doherty amplifying apparatus, comprising:
a linearization unit to linearize an applied signal through an analog pre-distortion;
a primary amplifier to amplify the linearized signal; and
a secondary amplifier to amplify the linearized signal.

2. The Doherty amplifying apparatus of claim 1, wherein the primary amplifier and the auxiliary amplifier amplify the linearized signal based on differing operation points.

3. The Doherty amplifying apparatus of claim 1, wherein the linearization unit is combined to a front portion of the primary amplifier.

4. The Doherty amplifying apparatus of claim 1, wherein the linearization unit is combined to a front portion of the secondary amplifier.

5. The Doherty amplifying apparatus of claim 1, wherein the linearization unit is combined to a front portion of the primary amplifier and the auxiliary amplifier.

6. The Doherty amplifying apparatus of claim 1, wherein the linearization unit detects an inter-modulation distortion (IMD) component of the applied signal.

7. The Doherty amplifying apparatus of claim 6, wherein the linearization unit performs inverse phasing with respect to a signal from which the IMD component is detected and applies the inverse-phased signal to the primary amplifier or the secondary amplifier.

8. A Doherty amplifying method, comprising:
linearizing an applied signal using a linearization unit through an analog pre-distortion;
amplifying the linearized signal using a primary amplifier; and
amplifying the linearized signal using a secondary amplifier.

9. The Doherty amplifying method of claim 8, wherein the primary amplifier and the secondary amplifier amplify the linearized signal based on differing operation points.

10. The Doherty amplifying method of claim 8, wherein the linearization unit is combined to a front portion of the primary amplifier.

11. The Doherty amplifying method of claim 8, wherein the linearization unit is combined to a front portion of the secondary amplifier.

12. The Doherty amplifying method of claim 8, wherein the linearization unit is combined to a front portion of the primary amplifier and the secondary amplifier.

13. The Doherty amplifying method of claim 8, wherein the linearization comprises:
detecting an inter-modulation distortion (IMD) component of the applied signal.

14. The Doherty amplifying method of claim 13, wherein the linearizing further comprises:
performing inverse phasing with respect to the signal from which the IMD component is detected and applying the inverse-phased signal to the primary amplifier or the secondary amplifier.
